(19) United States
(12) Patent Application Publication
(10) Pub. No.: US 2012/0192917 A1
(43) Pub. Date: Aug. 2, 2012

(54) SOLAR TRACKER MECHANISM

(76) Inventors: William H. Whitted, Woodside, CA (US); John S. Fitch, Los Altos, CA (US); Ross Koningstein, Menlo Park, CA (US)

(21) Appl. No.: 13/015,317

(22) Filed: Jan. 27, 2011

(51) Int. Cl. H01L 31/052; F24J 2/38

(52) U.S. Cl. 136/246; 126/600

(57) ABSTRACT

A solar tracker system includes a solar collector, a track, a movable assembly supporting the mirror, the movable assembly including track-traveling mechanism configured to move along the track when actuated by a first actuator to adjust an azimuth of the mirror, and a second actuator to adjust an elevation of the mirror.

### TECHNICAL FIELD

The present disclosure relates to solar trackers, e.g., heliostats or photovoltaic cell assemblies.

### BACKGROUND

A heliostat solar energy system generally includes a number of heliostats configured to reflect light into a receiver. The resulting heat can then be converted into power. Use of heliostats as a source of solar energy often requires receiver temperatures of nearly 1000° C., which in turn requires sunlight to be reflected from the heliostats into the receiver at high concentrations.

### SUMMARY

A simple mechanical design is provided to permit a solar collector of a solar tracker system to be oriented at the sun or to direct reflected sunlight to a receiver.

In one aspect, a solar tracker system includes a solar collector, a track, a movable assembly supporting the solar collector, the movable assembly including track-traveling mechanism configured to move along the track when actuated by a first actuator to adjust an azimuth of the solar collector, and a second actuator to adjust an elevation of the solar collector.

Implementations can include one or more of the following features. The track-traveling mechanism may be a rolling mechanism. The track may be substantial flat. The track may be a circular arc. The track may include elevation changes configured such that the solar collector follows a trajectory of the sun across the sky as the track travelling mechanism moves along the track. A base may support the track. The movable assembly may include a frame having a first end pivotally attached to the base at a pivot point. The solar collector may be hingedly attached to the first end of the frame. The frame may have a second end at which the track-traveling mechanism is positioned. The second actuator may be connected between the solar collector and the frame. The frame includes a telescopic mechanism to adjust a distance between the pivot point and the track-travelling mechanism. The track may include elevation changes and a lowest point of the track may be opposite the pivot point. The second actuator may be connected between the track and a base. The solar collector may be fixedly connected to the movable assembly. The track may be pivotally attached to the base. The movable assembly may include a frame having a first end pivotally attached to the base at a pivot point. The first end of the frame may be attached to the base by a compound hinge. The frame may have a second end at which the track-traveling mechanism is positioned. The track may include elevation changes and a lowest point of the track may be opposite the pivot point. The second actuator may include a first arm having a first end and a second end and a second arm having a first end and a second end, the first end of the first arm may be pivotally attached to the solar collector, the first end of the second arm may be pivotally attached to the frame, the second end of the first arm may be pivotally attached to the second end of the second arm, and a drive mechanism may adjust an angle between the first arm and the second arm. The drive mechanism may include a linear drive mechanism to adjust a distance between the frame and a point of pivotal attachment of the first arm to the second arm. The linear drive mechanism may include a rotatable rod having a first end connected to the frame and a second end in threaded engagement with the first or second arm. The drive mechanism may include a linear drive mechanism to adjust a distance between the base and a point of pivotal attachment of the first arm to the second arm. The linear drive mechanism may include a rotatable rod having a first end connected to the base and a second end in threaded engagement with the first or second arm. The solar collector may be a mirror or a photovoltaic cell assembly.

Potential advantages of implementations may include the following. The heliostat may be pointed with precision at the receiver at a lower cost, with less maintenance, less equipment, less calibration and simpler control algorithms. The heliostat can be started up or aligned rapidly without the need for time consuming hunting algorithms in the control system. The system can correct rapidly from cloud events, which shutter down the sun for periods of time. Finally, a viewing port within the harsh environment of the receiver region may not be needed if this technique can be used for precise heliostat pointing.

The details of one or more implementations are set forth in the accompanying drawings and the description below. Other aspects, features, and advantages will become apparent from the description, the drawings, and the claims.

### BRIEF DESCRIPTION OF THE DRAWINGS

FIG. 1 is a schematic diagram of a heliostat system.

FIG. 2 is a schematic diagram of an implementation of a heliostat.

FIG. 3 is a schematic diagram of an implementation of a heliostat that includes a track with varying elevations.

FIG. 4 is a schematic diagram of another implementation of a heliostat that includes a variable elevation track.

Like reference numbers and designations in the various drawings indicate like elements.

### DETAILED DESCRIPTION

Generation of power by a solar tracker can depend on proper orientation of the solar tracker. When heliostats are used as a source of heat (which can in turn be used as a source of power), the concentration of sunlight reflected into the heat-collecting receiver can be lower than the theoretical ideal. For example, heat loss can occur due to misalignment of the heliostat mirrors caused by errors such as difficulties detecting the orientation of the mirrors or relative position of the receiver, deformation of the mirror, or movement of the heliostat or receiver by natural causes. A sensor, such as a camera, can be used to determine where the heliostat mirrors are aiming their reflected light or heat. The brightness is dependent on the orientation of the heliostat mirrors. Adjusting the mirrors allows sunlight to be more accurately reflected into the receiver. Information collected by the sensor can be used to control an actuation system that changes the azimuth and/or horizontal to vertical angular rotation of the mirror. Thus, controlling the actuators to focus the reflected sunlight in the best location can allow for more efficient energy collection and generation. Similarly, generation of electrical power by a photovoltaic cell assembly can be less than the theoretical ideal if the photovoltaic cell assembly is not facing the sun.

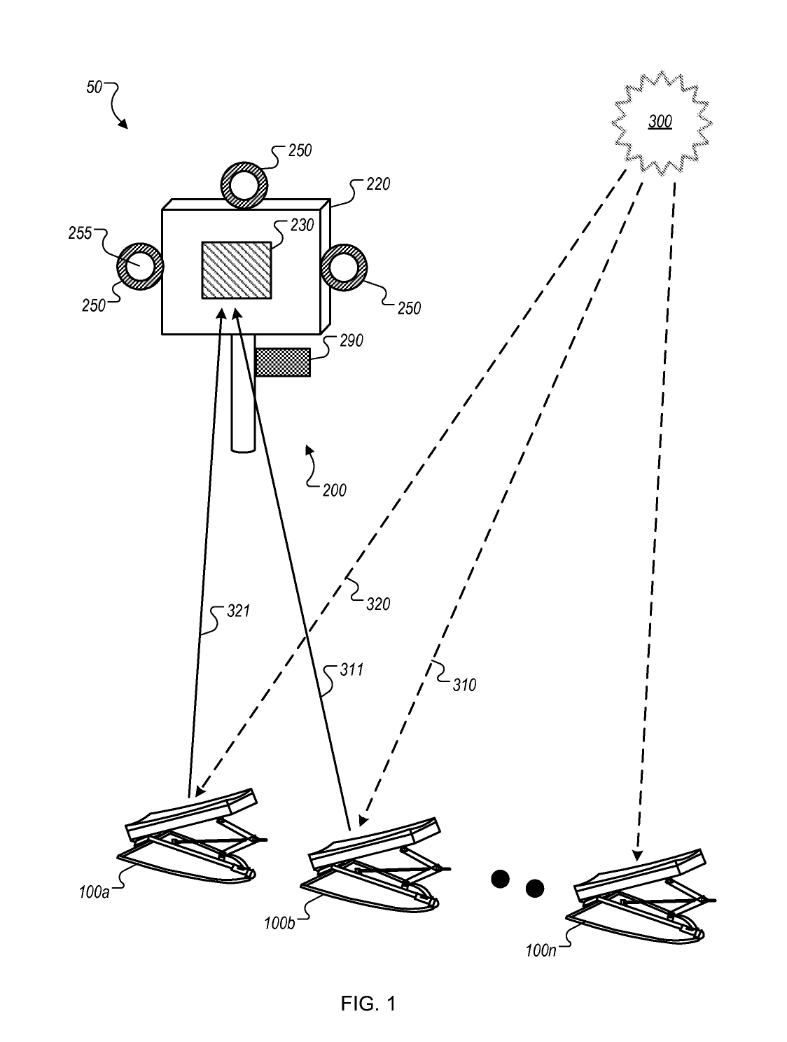

Referring to FIG. 1, a heliostat control system 50, e.g., for a solar power plant, includes a field of heliostats 100, which can include up to hundreds or thousands of heliostats (only three heliostats 100a, 100b and 100n are shown in FIG. 1).

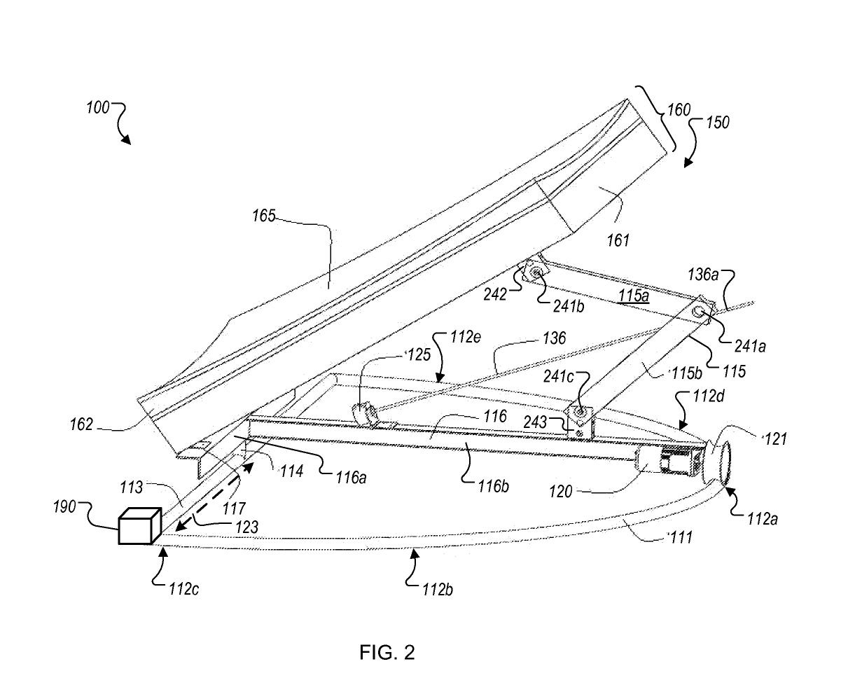

Referring to FIG. 2, a single solar tracker 100 in the form of a heliostat is shown. Each solar tracker 100 includes a solar collector 160 supported by a base 150. Assuming the solar tracker is a heliostat, each solar collector 160 can be a mirror which receives electromagnetic radiation, e.g., visible, near infrared and near ultraviolet light, from a source, such as the sun 300, and reflects the radiation to a receiver 230. Alternatively, assuming the solar tracker 100 is a photovoltaic cell assembly, each solar collector 130 can be a photovoltaic cell that converts electromagnetic radiation directly to electrical energy.

In the implementation shown in FIG. 2, the mirror 160 is pivotally attached, e.g., at a set of hinges 117, to a movable assembly, e.g., a T-shaped frame 116. The movable assembly can pivot relative to the base 150, e.g., about a generally vertical axis, i.e., perpendicular to the surface that the base 150 rests on so that the mirror can rotate about the vertical axis. In addition, because the mirror is pivotally attached to the movable assembly, the mirror 160 can pivot relative to the movable assembly and thus relative to the base 150, e.g., about a generally horizontal axis, i.e., parallel to the surface that the base 150 rests on.

The T-shaped frame 116 is mounted on (and can rotate upon) a pivot point 114 that is attached to a structural connection 113 of the base 150. Thus, the pivot point 114 permits the T-shaped frame 116 to rotate about a generally vertical axis, i.e., perpendicular to the surface that the base 150 rests on. The hinges 117 allow the mirror 160 to be positioned (e.g., tilted) at different altitudes relative to the base 150. The pivot point 114 allows the mirror 160 to be positioned (e.g., rotated) in various azimuths relative to the base 150.

In some implementations, the hinges 117 can include a single hinge, such as if the shape of the mirror 160 is diamond-shaped, e.g., with one corner of the diamond connected by the hinge to the frame. Assuming the mirror 160 has at least one generally straight edge, the straight edge of the mirror can be parallel to the top bar 116a of the T-shaped frame 116 and can be connected to the frame 116 by multiple hinges. Hinges 117 can be typical or spring-loaded. Hinges 117 can be made of flexible material (e.g., rubber or canvas systems), exhaust hangers, cable mounts, spring steel, or other compliant mechanisms.

The mirror 160 includes a reflective surface 165 on the face of the mirror 160 closest to the sun 300. The reflective surface 165 can be flat or curved (e.g., having a spherical or parabolic shape) for better optical performance. Moreover, the reflective surface 165 can be in the shape of a quadrilateral (e.g., a square or rectangle), or it can have rounded edges (e.g., be circular), to name a few examples. The mirror 160 includes a back support structure 161 and gap filling material 162 between the reflective surface 165 and the back support structure 161. The back support structure 161 need not have the same shape as the reflective surface 165, e.g., the reflective surface can be circular whereas the back support structure can be square or rectangular.

In general, assuming the solar tracker is a heliostat, the heliostat 100 is operated so that the normal to the reflective surface 165 of the mirror 160 bisects the angle between the sun 300 and the receiver 230 (see FIG. 1). This can provide the maximum light intensity on the receiver. Alternatively, assuming the solar tracker is a photovoltaic cell assembly, the solar tracker is operated so that the surface of the photovoltaic cell assembly is normal to the light from the sun.

The base 150 can support multiple actuators (e.g., motors) that can move the mirror 160 in various directions relative to the base 150. A first actuator 120 is operable to move the mirror 160 in the azimuth direction. As shown, the first actuator 120, attached to the shank 116b of the frame 116, includes a motor and can control a track-travelling mechanism, e.g., a rolling mechanism 121 (e.g., a wheel, roller, toothed gear, inflatable tire, etc.), or a sliding mechanism, that can roll or move along a track 111. A proximal end of the shank 116b can be connected to the pivot point 114, whereas a distal end (relative to the hinge 117 and pivot point 114) of the shank 116 can be connected to the rolling mechanism 121. For example, the first actuator 120 can turn the rolling mechanism 121, moving the distal end (relative to the hinge 117) of the shank 116b to various locations along the track 111, such as at a position 112a. Simultaneously, as the rolling mechanism 121 moves along the track 111, the mirror 160 pivots at the pivot point 114 relative to the base 150. This occurs because the position of the frame 116 relative to the hinged end of the mirror 160 does not change. As a result, the azimuth of the mirror 160 is adjusted, such as to aim the mirror 160 at an angle that directs the sunlight to the receiver.

In some implementations, the rolling mechanism 121 includes a set of rollers (e.g., two or more) that can “capture” the track (e.g., along the top and bottom, or two or more sides). This can prevent the rolling mechanism 121 from leaving the track. In other implementations, the heliostat 100 omits the use of the track 111, and instead the rolling mechanism 121 simply rolls across the ground.

In the implementation shown in FIG. 2, the shape of the track 111 is a semi-circle of the circle having a radius 123 that is defined by the length of structural connection between the pivot point 114 and the rolling mechanism 121, e.g., the radius 123 corresponds to the length of the shank 116b.

In some implementations of the heliostat 100, other shapes of the track 111 are possible, and in those cases, the frame 116, e.g., the shank 116b, can include telescoping capabilities to match the shape of the track 111, allowing the rolling mechanism 121 to stay engaged with the track 111.

Other positions of the rolling mechanism 121 are possible than the position 112a, shown, such as positions 112b-112e, as are infinite other positions in between. In the position 112b, for example, the rolling mechanism 121 has traveled approximately 45 degrees of arc along the track 111 from the position 112a, simultaneously moving the frame 116, and thus the mirror 160 in the same direction. This changes the azimuth of the mirror 160 accordingly. In the position 112c, for example, the rolling mechanism 121 has traveled approximately 90 degrees of the arc along the track 111 (relative to the position 112a). In the implementation of the base 150 shown in FIG. 2, the track 111 provides approximately 180 degrees of arc upon which the rolling mechanism 121 can move. Other implementations of the heliostat 100 can include tracks 111 with degrees of arc that approach 360 degrees, for example, which can receive the rays of the sun 300 on the longest summer days.

Tracks 111 can be manufactured using various materials, such as metal or plastic tubing, and so on. Selection of the materials used can depend, for example, on the climate of the location in which the heliostats 100 are to be installed, cost factors, the expected lifetime of the system, maintenance considerations, and so on.

A second actuator 125 is operable to move the mirror 160 in the elevation direction. The second actuator 125 (e.g., a motor) can be attached to the frame 116, e.g., relatively proximate to the hinged end (e.g., at the hinge 117) of the mirror 160. The second actuator 125 can be connected to a rotatable rod 136 that can include a threaded end 136a that engages with an elevation adjustment arm 115 that is configured to change the elevation angle of the mirror 160. As an example, during operation of the heliostat 100, the second actuator 125 can operate (e.g., turn or rotate) the rod 136, allowing the rod 136 to serve as a lengthening mechanism relative to its threaded attachment point with an elevation adjustment arm 115. In this way, the elevation angle of the mirror 160 can be changed.

The elevation adjustment arm 115 includes a top joint 115a and a bottom joint 115b, joined at a first movable pivot 241a. In some implementations, the movable pivot 241a includes a floating nut, and the rod 136 is threaded through the floating nut. At a second movable pivot 241b, the top joint 115a is attached to a tab 242 that is joined to the bottom side of the mirror 160. At a third movable pivot 241c, the bottom joint 115b is attached to a tab 243 that is joined to the top surface of the frame 116. When the second actuator 125 turns the rod 136 in one direction (e.g., clockwise), the distance decreases between the second actuator 125 and the first movable pivot 241a. At the same time, the joints 115a and 115b straighten out so that the distance increases between the pivots 241b and 241c, thus increasing the distance between tabs 242 and 243. As a result, the tilt of the mirror 160 increases, forcing the mirror into a more horizontal orientation and aiming the mirror 160 at a lower elevation. Conversely, when the second actuator 125 turns the rod 136 in the other direction (e.g., counter-clockwise), the distance increases between the second actuator 125 and the first movable pivot 241a, which effectively folds up the elevation adjustment arm 115, so that the distance between the pivots 241b and 241c decreases, thus decreasing the distance between tabs 242 and 243. As a result, the tilt of the mirror 160 decreases, moving the mirror into a more vertical orientation and aiming the mirror 160 at a higher elevation.

In some implementations, the linkage and elevation actuator 125 and elevation adjustment arm 115 can be replaced with an air bladder. For example, air can be pumped into the bladder to raise the mirror 160 (e.g., to decrease its elevation angle), or removed from the bladder as needed (e.g., to lower the mirror 160 to a more horizontal position).

For each heliostat 100 in a field of heliostats, the heliostat 100 can include a transceiver 190 capable of receiving commands from a heliostat control system 50 and sending control signals to the actuators 120, 125 that direct the movement of the mirror 160. In some implementations, the transceiver 190 can be mounted on the base 150. In other implementations, the transceiver 190 can be mounted along the side of the mirror 160. Communication between the transceiver 190 and the actuators 120, 125 can occur using wires (not shown) or through wireless communication.

In some implementations, the actuators 120, 125 can use hydraulic (e.g., hydraulic cylinders), pneumatic (e.g., pneumatic cylinders), cable and pulley/capstan, bladder, ballasted, or ball and socket mechanisms to move the heliostat mirror 160 in the azimuth direction and/or to adjust the altitude. Some implementations of the actuators can include the use of levers, hinges and pivot points.

In some implementations, in addition to the actuators 120, 125 for changing the position of the mirror 160, the heliostat 100 can include a cam system. For example, the cam can prop the frame 116 up and down at various states of rotation. This cam can be indexed such that it changes each day. As it finishes rolling for any particular day, at the end of its journey, the cam can automatically ratchet into a new position for the next day.

Referring back to FIG. 1, the heliostat control system 50 includes a tower system 200. The tower system 200 includes a receiver 230 to receive sunlight and one or more sensors, such as cameras 250, each of which can optionally include a filtering element 255 to reduce the intensity of the sunlight, and an optical element to expand, contract, or condition the sunlight as necessary prior to entry of the beam into the camera. The receiver 230 can be shaped to receive concentrated sunlight, such as by being circular in shape. The region in which the receiver 230 is located can be called the “receiver volume” or the “hot region” of the tower system 200. The receiver 230 can be located inside a housing 220 and can sit on top of a foundation structure 210, which can be partially below ground.

The heliostat control system 50 further includes a controller or computer 290 to receive image data from the cameras 250, to compute the movement of any heliostat mirrors 160 necessary to keep the heliostats 100 oriented to reflect light to the receiver 230, and to send commands to the transceivers 190 of the heliostats 100. The computer 290 can be part of the tower system 200, as shown in FIG. 1.

In operation, sunlight rays 320, 310 from the sun 300 can strike the reflective surface 165 of the heliostat mirrors 160. The reflective surface 165 can then reflect rays 321, 311 towards the receiver 230. The reflected rays 321, 311, in addition to rays reflected from other heliostats in the field, can heat the receiver 230 to temperatures of between 900° C. and 1200° C., such as between 950° C. and 1150° C. The heat can be used to drive various heat engines to produce power. For example, the heat can be used to warm cold air, which can then be expanded through a turbine engine which turns a generator shaft, which creates power. The more concentrated the sunlight is in the receiver 230, the higher the temperature of the receiver 230, and the more efficient the power generation of the system 50 can be.

To maximize the direct concentrated rays towards the receiver 230, the normal vector of the reflective surface 165 should bisect the angle between the rays 310, 320 from the sun 300 and the rays reflected towards the center of the receiver 230. Thus, as the sun 300 moves across the sky, the orientation of the reflective surface 165 of the mirrors 160 must be adjusted to ensure that the reflected rays are hitting the receiver 230 without causing too much spillage, i.e., causing too many rays to be reflected outside of the receiver 230.

The camera 255 mounted on the receiver 230 can be used to determine whether a particular mirror 160 is oriented to reflect substantially the maximum amount of light into the receiver, i.e., to orient the reflective surface 165 such that its normal vector substantially bisects the angle between the rays from the sun 300 and the rays reflected towards the receiver 230. When rays from the heliostats 100 are reflected into the receiver 230, and correspondingly to the camera 255, the camera 255 observes and produces an image. The image produced by the camera 250 can include pixels having a brightness dependent on the orientation of the various heliostats. As a result, as discussed below, the image can be used to determine an error in the orientation of the mirrors.

A calibration step can be required prior to determining the actual error in orientation of a heliostat 100. During calibration, the assignment of a particular heliostat 100 to a set of pixels in the camera's imaging array can be determined. For example, during the calibration step, the camera 250 can observe and produce an image of the heliostat field. Portions of the image, or groups of pixels, can be assigned to a particular heliostat. In some implementations, the heliostat can be oscillated at a known frequency. The computer 290 can then watch for that frequency of blinking in the image in order to identify that heliostat in the pixel array of the image. Proceeding through each of the heliostats, one at a time, each heliostat in an entire field of heliostats may be identified. Such a mechanism is important for unique identification of each heliostat. The computer 290 can maintain a database having the positions of all of the various heliostats in the field and the portions of the image corresponding to each of those heliostats.

Because there are generally multiple heliostats in a field, it may be advantageous to be able to detect when a heliostat 100 is physically moved, or when a particular heliostat 100 is added or removed from the field. Thus, in some implementations, any new bright images that seem out of place may be compared with the original calibration images to look for changes. The system 50 can automatically detect the positions of all of the heliostats 100 in the field and recalibrate as necessary.

After the computer 290 has assigned a portion of an image to each heliostat 100 in a field, the system 50 can be used to determine an error in an orientation of the mirrors (e.g., to determine whether the mirror 160 is oriented to reflect a maximum amount of light into the receiver 230) and subsequently to change the orientation of the mirrors 160 such that they reflect substantially the maximum amount of light into the receiver 230. To do so, the computer 290 can try to maximize the sunlight seen by the camera 250 from each heliostat 100. If a portion of the image assigned to a particular heliostat does not include a bright spot or includes a spot that is not as bright as expected, then the computer 290 can determine that the mirror 160 for that heliostat is not oriented accurately. For example, in FIG. 1, ray 321 is not hitting the center of the receiver 230. As a result, the image produced by the camera 250 will not be as bright as expected in the portion of the image corresponding to heliostat 100b.

The computer 290 can send a command to actuators on a particular heliostat, such as heliostat 100b in FIG. 1, to direct the heliostat to move its mirror 160 accordingly. For example, the computer 290 can send a command, such as through a wireless or wired signal, through a transceiver 190 on the heliostat, which can in turn send a signal to the actuators 120, 125 on the heliostat 100. The actuators can in turn adjust the mirrors 160 as directed.

For example, the actuator 120 might first be commanded by the computer 290 to move a mirror 160 of a heliostat in a particular direction along the azimuth. If the brightness for the portion of the image assigned to that heliostat increases, then the computer 290 can command the actuator 120 to continue to move the mirror 160 in that direction. In contrast, if the brightness decreases, then the computer 290 can command the actuator 120 to move the mirror 160 in the opposite direction. These adjustment steps can then be repeated for elevating the mirror with actuator 125.

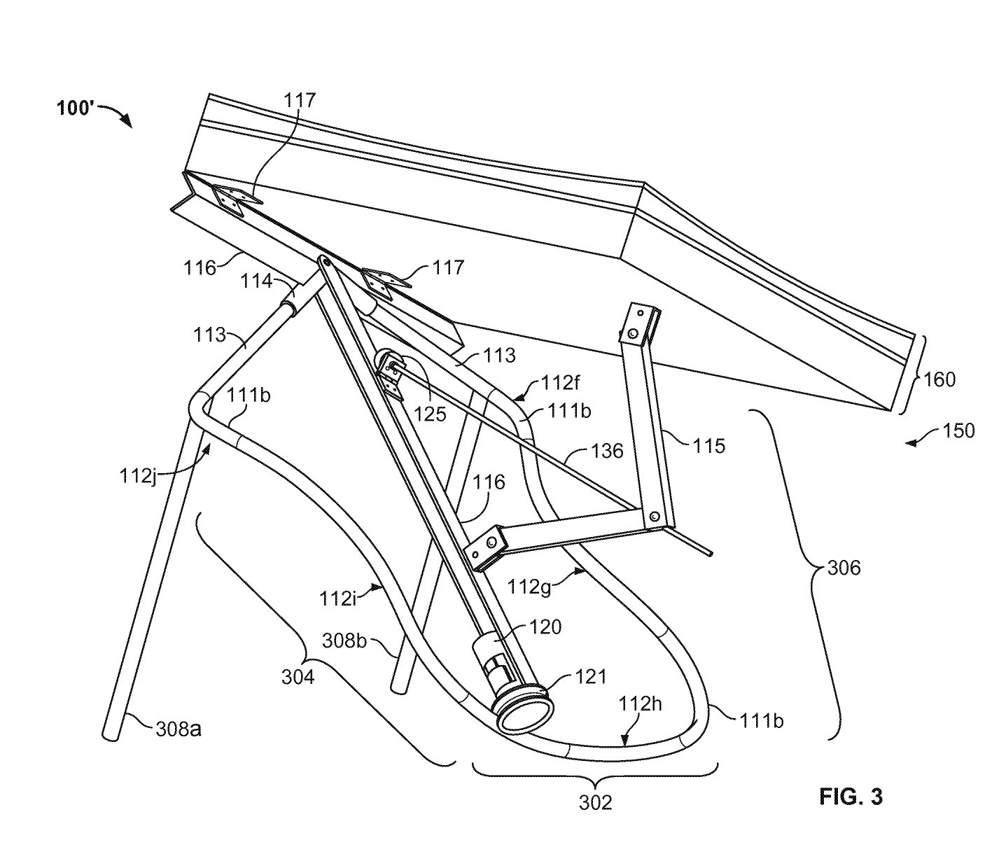

FIG. 3 is a schematic diagram of another implementation of a heliostat actuation system. This implementation the heliostat 100′ includes a track 111b with varying elevation. The track 111b is curved so that a center portion 302 of the track 111b rests on or near the ground, and portions 304 and 306 are positioned significantly off the ground. The non-flat shape of the track 111b differs from the flat shape of the track 111 described above with reference to FIG. 2. The shape of the track 111b can allow gross elevation adjustments, e.g., when the rolling mechanism 121 follows the track 111b, the elevation of the mirror is adjusted without significant participation from the elevation actuator 125. The shape of the track 111b can be an average path computed from all days of the year, location in the field, expected energy intensities, and so on.

The portions 304, 306 of the track 111b rise gradually from the center portion 302 to the ends of the track 111b nearest the structural connection 113 of the base 150. In this configuration of the base 150, instead of the track 111b being relatively flat against the ground (and providing the support for the mirror 160), the base 150 includes legs 308a and 308b, which serve to lift the portions 304 and 306 off the ground relative to the portion 302 and also provide support for the mirror 160. The resulting shape of the track 111b can allow the actuator 120 to perform the majority of the work needed to aim the mirror 160 at elevations needed to follow the course of the sun 300 during a typical day. This occurs simply by using the elevation changes in the track 111b. As a result, significantly less work may be required by the actuator 125 during the day, except, for example, to move the arm 115 as needed to fine-tune the elevation angle of the mirror 160, e.g., to compensate for seasonal changes.

As an example of a daily cycle using the track 111b and its built-in elevation changes, the rolling mechanism 121 can begin at a position 112f on the track 111b that generally aims the mirror 160 at a low elevation to capture early morning sunlight. In this case, the position 112f is the highest elevated position on the track 111b on that side of the track 111b. Over time, such as later on in the morning, the rolling mechanism 121 moves along the track, e.g., to change the azimuth angle of the mirror 160. As this occurs, the rolling mechanism 121 can reach new positions on the track 111b, such as a position 112g (e.g., at mid-morning). In this position 112g, as the rolling mechanism 121 has dropped in elevation, the mirror 160 tilts upward to a higher elevation, approximately matching the location of the sun 300 in the sky. Movement of the arm 115 is still required by the actuator 125 in order to precisely position the mirror 160 relative to the sun 300. At mid-day, the rolling mechanism 121 can reach a position 112h on the track 111b, or its lowest elevation, which in turns aims the mirror 160 to its highest elevation. Movement of the rolling mechanism 121 can continue during the day, reaching positions 112i (e.g., at mid-afternoon) and 112j (e.g., before dusk). Before the start of the next day, the actuator 120 can re-position the rolling mechanism 121 to its start-of-day position 112f, ready for the next sunny day.

On any particular day, the shape of the track 111b can facilitate movement of the mirror 160 in a left-to-right, low-to-high-to-low direction to match the natural movement of the sun 300 (e.g., in the Northern Hemisphere). The direction of movement along the track 111b can be reversed in the Southern Hemisphere. In general, different shapes of tracks 111b can be manufactured for different latitude bands of the world, as well as to factor in variations due to changes of the seasons. In some implementations, the same tracks 111b can be used throughout the year, and while long days (e.g., during summer) can result in using the entire length of the track 111b during the day, short days (e.g., during winter) can result in using less of the track 111b, such as the middle portion between positions 112g and 112i.

In some implementations, such as to facilitate the movement of the rolling mechanism 121 along the tracks 111 and 111b, linkages of various shapes and geometries can be used, which can provide different rates and precisions of change.

In implementations of the rolling mechanism 121 that use an inflatable tire, the pressure of the tire can change along the outside rolling diameter to account for elevation adjustments in the track 111b.

In some implementations of the heliostat 100, the actuator 120 is omitted from the system. In its place, a mechanism connects near that point of the frame 116 and moves the frame 116. The mechanism can also work on adjacent heliostats 100. The mechanism can be cable-driven at the perimeter of the heliostat field, or use a linkage. The rolling mechanism 121 can travel on the track 111 or on the ground. This type of mechanism can adjust the heliostats 100 grossly, while another mechanism on each heliostat 100 can make micro corrections.

In some implementations, the actuators 120, 125 can be replaced with a single actuator combined with another mechanism such that the single actuator can make adjustments to either of the two directions. For example, single actuators of this type can use a clutch and brake mechanism. In some implementations, in order to save costs (e.g., costs per heliostat 100), actuators on individual heliostats 100 can be replaced by multi-heliostat actuators that apply motions to several heliostats 100.

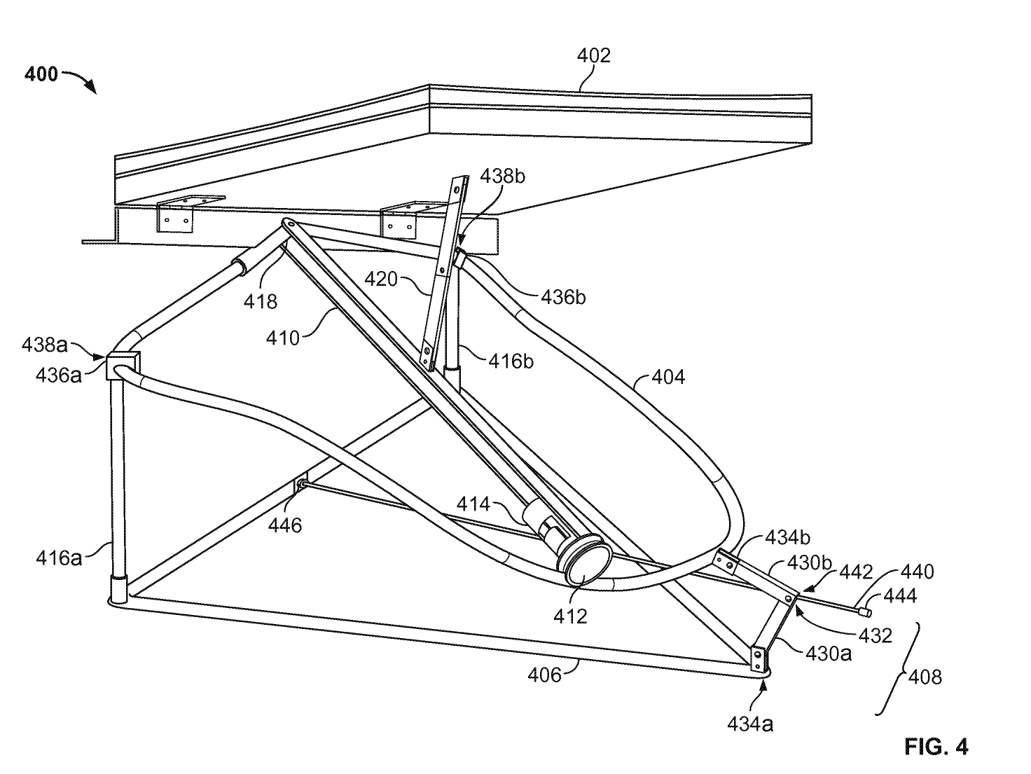

FIG. 4 is a schematic diagram of another implementation of a heliostat actuation system. This implementation shows a heliostat 400 that includes a mirror 402 that is adjustable in the elevation and azimuth directions, which is similar to the heliostat 100′ described above with reference to FIG. 3. However, in the heliostat 400, the mirror is fixed in position relative to a frame 410 that rides along a sinusoidal track 404. Thus, the mirror 402 is adjustable in the elevation and azimuth directions by adjusting the position of the frame 410 along on the track 404, e.g., by having the rolling mechanism 412 roll along the track. In addition, the sinusoidal track 404 itself is adjustable in elevation (e.g., by tilting), relative to a base 406, using an adjustment mechanism 408.

For example, the adjustment mechanism 408 can adjust the elevation angle of the sinusoidal track 404 on a scheduled basis (e.g., each night), to correspond to daily changes in the sun's angle relative to the geographical location of the heliostat 400. Then, during daylight hours, when the sinusoidal track 404 is at a particular elevation angle (e.g., as set by the adjustment mechanism 408), the frame 410 connected to the mirror 402 can change the azimuth and elevation of the mirror 402 in order to follow the trajectory of the sun 300 across the sky.

In some implementations, a first end of the frame 410 can be pivotally attached to the base 406, and a second end of the frame 410 can movably engage the track 404. A roller 412 or other mechanism attached at the second end of the frame 410 can roll along the sinusoidal track 404. An actuator 414, such as a motor, can control the roller 412 in similar ways as explained above for rollers and actuators described with reference to FIG. 3. The base 406 of the heliostat 400 includes legs 416a and 416b, and can also include a support strut 417 connected between the legs 416a and 416b. The first end of the frame 410 can be pivotally attached to the strut 417, e.g., at a point between legs 416a and 416b, e.g., to the center of the strut 417. The legs 416a and 416b can support the front edge of the sinusoidal track 404.

The frame 410 attaches to the strut 417 at a hinge 418. The hinge 418 is a compound hinge, allowing the frame 410 and mirror 402 to change in elevation and azimuth as the roller 412 end of the frame 410 moves, e.g., as the roller 412 rolls along the sinusoidal track 404. The mirror 402 is attached to the frame 410 by an upper support arm 420. The upper support arm can be attached to the bottom side of the mirror 402 at a connection point 422 at about the center of the mirror and be attached to the frame 410 at about the center of the frame 410. The length of the support arm is exaggerated; the mirror 402 can be located in proximity to the frame 410. As an example, the mirror 402 and the sinusoidal track 404 can be approximately parallel to one another, or as co-planer as possible.

The adjustment mechanism 408 can include multiple components that work together to change the elevation angle of the sinusoidal track 404 relative to the base 406. As depicted in the implementation of FIG. 4, the adjustment mechanism 408 includes a lower arm 430a and an upper arm 430b, connected together at a hinge 432. The bottom of the lower arm 430a is connected to the base 406 at a hinge 434a. The top of the upper arm 430b is attached to the sinusoidal track 404 at a hinge 434b. As shown, the hinge 434b is positioned at a point on the sinusoidal track 404 that is halfway between a pair of hinges 436a and 436b along the front edge of the heliostat 400 (e.g., the edge closest to the sun 300). The hinges 436a and 436b define a line along the edge the heliostat 400 about which the adjustment mechanism 408 pivots the sinusoidal track 404 so as to tilt the mirror 402. The hinges 436a and 436b can be connected to the strut 417 at the tops of the legs 416a and 416b.

The adjustment mechanism 408 can further include a threaded rod 440 and a nut 442. The nut 442 is attached inside of (or adjacent to) the hinge 412. The nut 442 is attached to the threads of the threaded rod 440. The adjustment mechanism 408 can further includes a motor 444 that is operable to turn the threaded rod 440. In some implementations, the motor 444 can be connected to the base 406 and can turn the threaded rod 440 when needed. When the motor 444 turns the threaded rod 440, the nut 442 is engaged, which in turn changes the distance between the nut 442 and a hinge 446 attached at the front edge (e.g., closest to the sun 300) of the base 406. As a result, the angle between the arm 430a and 430b changes, effectively changing the distance between the back edge of the sinusoidal track 404 and the base 406.

In one example operation of the adjustment mechanism 408, a control system (not shown) can operate the motor 444 at night to change the elevation angle of the sinusoidal track 404 so that the heliostat 400 is positioned for the expected trajectory of the sun 300 for the next day. The action of the motor 444 turning the threaded rod 440 in one direction, for example, can raise the back end of the sinusoidal track 404 relative to the base 406. This direction of turn can occur when days are getting shorter and the elevation angle of the mirror 402 is generally lower in the sky. Conversely, the action of the motor 444 turning the threaded rod 440 in opposite direction, for example, can lower the back end of the sinusoidal track 404 relative to the base 406. This direction of turn can occur when days are growing longer (e.g., having more hours of sunlight) and the elevation angle of the mirror 402 is generally higher in the sky.

The implementation of the heliostat 400 depicted in FIG. 4 includes many potential advantages and alternate implementations. For example, because the heliostat 400 requires no continuous elevation adjustment, e.g., only a once-a-day change to a new seasonally-determined position, the power needed to position the heliostat 400 can be significantly reduced. Also, with this implementation, the need for closed-loop control of either the elevation or the azimuth can be obviated, as the system becomes a pure clock-work device. In some implementations, occasional monitoring might still be desirable to initialize the mirror 402 position (e.g., to initially synchronize it to local solar time) and to ensure that re-initialization of the mirror 402 can be requested should the heliostat 400 get bumped or shaken out of position (e.g., for the desired, time, season and latitude). However, in general, the costly and complex need for real-time monitoring could be eliminated. The implementation of the heliostat 400 further allows for a regulated, mechanical, clockwork-drive device requiring only periodic winding (e.g., a totally non-precision application of power). In some implementations, the winding power can be applied to multiple heliostats simultaneously, requiring little more than a single, large, computer-operated, on-off switch. In some implementations, the power can also come from a ganged mechanical system.

In some implementations, the adjustment mechanism 408 can operate as needed during the day, for example, in order to reduce the amount of slope needed for the sinusoidal track 404. For example, on long summer days when the sun 300 travels in a large arc across the sky (e.g., as compared to a relatively shorter, winter day), the adjustment mechanism 408 can make elevation adjustments that affect the elevation angle of the sinusoidal track 404, and thus the mirror 402.

In some implementations, the rear-most corner of the base 406 (e.g., at the hinge 432a) can be closer to the front of the heliostat 400, such as directly below the hinge 432b. In this configuration, for example, the length of arms 430a and 430b could be shorter, thus requiring less material for their manufacture.

In some implementations, the adjustment mechanism 408 can be positioned closer to the hinge 446 attached at the front edge. For example, in this location, the adjustment mechanism 408 can provide a greater angular lift (e.g., in a range that includes 11.5 degrees) of the sinusoidal track 404, and thus the mirror 402.

In some implementations, the base 406 can be installed so that the heliostat 100 is positioned to optimize the nominal mirror 402 tilt for the latitude of the heliostat's installation site. For example, installation position adjustments can be accomplished using one or more adjustable back legs attached to the base 406 at or near the hinge 434a. In some implementations, the heliostat 100 can be installed or fixed to the ground using mounting piers (e.g., three or more) set at appropriate heights in order to position the heliostat 400 at an optimum elevation angle relative to the sun 300.

Although the discussion above has focused on implementations (in FIGS. 1-4) in which the solar tracker is a heliostat, the same support structure (i.e., the components below the solar collector) can be used for a photovoltaic cell assembly. In this case, rather than a mirror, a photovoltaic cell assembly that converts electromagnetic radiation directly to electrical power can be supported on the base 150. The photovoltaic cells can create a DC output voltage, and can be connected to electrical aggregation circuitry to create a high voltage source.

Particular implementations have been described. Other implementations are within the scope of the following claims.

What is claimed is:

1. A solar tracker system, comprising:
a solar collector;
a track;
a movable assembly supporting the solar collector, the movable assembly including track-traveling mechanism configured to move along the track when actuated by a first actuator to adjust an azimuth of the solar collector; and
a second actuator to adjust an elevation of the solar collector.

2. The solar tracker system of claim 1, wherein the track-traveling mechanism is a rolling mechanism.

3. The solar tracker system of claim 1, wherein the track is substantially flat.

4. The solar tracker system of claim 3, wherein the track is a circular arc.

5. The solar tracker system of claim 1, wherein the track includes elevation changes configured such that the solar collector follows a trajectory of the sun across the sky as the track travelling mechanism moves along the track.

6. The solar tracker system of claim 1, further comprising a base supporting the track.

7. The solar tracker system of claim 6, wherein the movable assembly includes a frame having a first end pivotally attached to the base at a pivot point.

8. The solar tracker system of claim 7, wherein the solar collector is hingedly attached to the first end of the frame.

9. The solar tracker system of claim 8, wherein the frame has a second end at which the track-traveling mechanism is positioned.

10. The solar tracker system of claim 9, wherein the second actuator is connected between the solar collector and the frame.

11. The solar tracker system of claim 9, wherein the frame includes a telescopic mechanism to adjust a distance between the pivot point and the track-traveling mechanism.

12. The solar tracker system of claim 7, wherein the track includes elevation changes and a lowest point of the track is opposite the pivot point.

13. The solar tracker system of claim 7, wherein the second actuator comprises a first arm having a first end and a second end and a second arm having a first end and a second end, the first end of the first arm pivotally attached to the solar collector, the first end of the second arm pivotally attached to the frame, the second end of the first arm pivotally attached to the second end of the second arm, and a drive mechanism to adjust an angle between the first arm and the second arm.

14. The solar tracker system of claim 13, wherein the drive mechanism comprises a linear drive mechanism to adjust a distance between the frame and a point of pivotal attachment of the first arm to the second arm.

15. The solar tracker system of claim 14, wherein the linear drive mechanism comprises a rotatable rod having a first end connected to the frame and a second end in threaded engagement with the first or second arm.

16. The solar tracker system of claim 1, further comprising a base, and wherein the second actuator is connected between the track and the base.

17. The solar tracker system of claim 16, wherein the solar collector is fixedly connected to the movable assembly.

18. The solar tracker system of claim 16, wherein the track is pivotally attached to the base.

19. The solar tracker system of claim 18, wherein the movable assembly includes a frame having a first end pivotally attached to the base at a pivot point.

20. The solar tracker system of claim 19, wherein the first end of the frame is attached to the base by a compound hinge.

21. The solar tracker system of claim 19, wherein the frame has a second end at which the track-traveling mechanism is positioned.

22. The solar tracker system of claim 21, wherein the track includes elevation changes and a lowest point of the track is opposite the pivot point.

23. The solar tracker system of claim 16, wherein the second actuator comprises a first arm having a first end and a second end and a second arm having a first end and a second end, the first end of the first arm pivotally attached to the track, the first end of the second arm pivotally attached to the base, the second end of the first arm pivotally attached to the second end of the second arm, and a drive mechanism to adjust an angle between the first arm and the second arm.

24. The solar tracker system of claim 23, wherein the drive mechanism comprises a linear drive mechanism to adjust a distance between the base and a point of pivotal attachment of the first arm to the second arm.

25. The solar tracker system of claim 24, wherein the linear drive mechanism comprises a rotatable rod having a first end connected to the base and a second end in threaded engagement with the first or second arm.

26. The solar tracker system of claim 1, wherein the solar collector is a mirror.

27. The solar tracker system of claim 1, wherein the solar collector is a photovoltaic cell assembly.
